(19) United States
(12) Patent Application Publication
(10) Pub. No.: US 2025/0101298 A1
(43) Pub. Date: Mar. 27, 2025

(54) QUANTUM DOT, METHOD FOR PREPARING THE QUANTUM DOT, AND LIGHT EMITTING ELEMENT COMPRISING THE QUANTUM DOT

(71) Applicant: Samsung Display Co., Ltd., Yongin-si (KR)

(72) Inventors: SUNGJAE KIM, Yongin-si (KR); Youngsik KIM, Yongin-si (KR); Hongrae KIM, Yongin-si (KR); Bitna YOON, Yongin-si (KR); DONGHEE LEE, Yongin-si (KR); TAEKJOON LEE, Yongin-si (KR); JUNEHYUK JUNG, Yongin-si (KR)

(73) Assignee: Samsung Display Co., Ltd., Yongin-si (KR)

(21) Appl. No.: 18/758,011

(22) Filed: Jun. 28, 2024

(30) Foreign Application Priority Data
Sep. 27, 2023 (KR) 10-2023-0129988

(51) Int. Cl. C09K 11/62; C09K 11/58; H01L 33/50; H10K 50/115; H10K 50/155

(52) U.S. Cl. CPC C09K 11/626; C09K 11/584; C09K 11/623; H10H 20/8512; H10K 50/115; H10K 50/155; C09K 2211/10

(57) ABSTRACT

Embodiments provide a quantum dot, a method for preparing a quantum dot, and a light emitting element including the quantum dot. The method for preparing a quantum dot includes forming a core including a copper atom, an indium atom, a gallium atom, and a sulfur atom, and forming a shell surrounding the core by reacting the surface of the core with hydrofluoric acid, a Group II element precursor, and a Group VI element precursor.

### CROSS-REFERENCE TO RELATED APPLICATION(S)

This application claims priority to and benefits of Korean Patent Application No. 10-2023-0129988 under 35 U.S.C. § 119, filed on Sep. 27, 2023 in the Korean Intellectual Property Office, the entire contents of which are incorporated herein by reference.

### BACKGROUND

### 1. Technical Field

The disclosure herein relates to a quantum dot, a method for preparing the quantum dot, and a light emitting element including the quantum dot.

### 2. Description of the Related Art

Various display devices for use in multimedia devices such as a television, a mobile phone, a tablet computer, a navigation unit, and a game console are being developed. In such a display device, a so-called self-luminescent display element may be used that achieves display by causing a luminescent material including an organic compound to emit light.

Development of a light emitting element using quantum dots as a luminescent material is underway as an effort to enhance the color reproducibility of display devices, and there is a demand for improving the luminous efficiency and service life of a light emitting element using quantum dots.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a quantum dot exhibiting a high quantum yield and excellent chemical stability.

The disclosure provides a light emitting element having improved luminous efficiency and color reproducibility.

An embodiment provides a method for preparing a quantum dot, which may include forming a core including a copper atom, an indium atom, a gallium atom, and a sulfur atom, and forming a shell surrounding the core by reacting the surface of the core with hydrofluoric acid, a Group II element precursor, and a Group VI element precursor.

In an embodiment, the forming of the shell may include: reacting the surface of the core with the hydrofluoric acid; and reacting the surface of the core with the Group II element precursor and the Group VI element precursor, wherein halogen ions bonded to the surface of the core may be removed through the reacting of the surface of the core with the hydrofluoric acid.

In an embodiment, the number of moles of the hydrofluoric acid may be in a range of about 2 times to about 7 times with respect to the total number of moles of the copper atom, the indium atom, the gallium atom, and the sulfur atom.

In an embodiment, the forming of the core may include: providing a first mixture including a ligand and a first precursor material including a copper precursor, an indium precursor, and a gallium precursor; and adding a sulfur precursor to the first mixture to react the first precursor material with the sulfur precursor.

In an embodiment, the copper precursor, the indium precursor, and the gallium precursor may each be a metal halide.

In an embodiment, the copper precursor may be represented by Formula 1, the indium precursor may be represented by Formula 2, and the gallium precursor may be represented by Formula 3:

CuXₘ [Formula 1]

InXₘ [Formula 2]

GaXₘ [Formula 3]

In Formula 1 to Formula 3, X may be Cl, Br, or I, and m may be determined according to the valence of Cu, In, or Ga, and may each independently be an integer from 1 to 3.

In an embodiment, the sulfur precursor may include at least one of sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, and bis(trimethylsilyl) sulfide.

In an embodiment, the forming of the shell may include adding a Group II element precursor and a solvent including the hydrofluoric acid to a second mixture including the core, and adding a Group VI element precursor to the second mixture to react the Group II element precursor and the Group VI element precursor.

In an embodiment, the reacting of the Group II element precursor and the Group VI element precursor may each be performed at a first temperature, and the first temperature may be equal to or greater than about 160° C.

In an embodiment, the adding of the solvent containing the hydrofluoric acid may be performed at a second temperature that is lower than the first temperature.

An embodiment provides a quantum dot which may include: a core including copper, indium, gallium, and sulfur; and a shell surrounding the core and including fluorine and a Group II-VI compound.

In an embodiment, the Group II-VI compound may be ZnS.

In an embodiment, an average particle diameter of the quantum dot may be in a range of about 3 nm to about 20 nm.

In an embodiment, a central wavelength of the quantum dot may be in a range of about 500 nm to about 650 nm.

In an embodiment, a full width at half maximum (FWHM) of an emission wavelength spectrum of the quantum dot may be equal to or less than about 60 nm.

In an embodiment, a quantum yield of the quantum dot may be equal to or greater than about 80%.

In an embodiment, a quantum yield retention rate of the quantum dot may be represented by Equation 1, and the quantum yield retention rate may be equal to or greater than about 90%:

$$Quantum yield retention rate = {A}_{1} / A 0 \qquad [ Equation l ]$$

In Equation 1, A1 may be a quantum yield of the quantum dot measured when blue light having a brightness of 200 nit is emitted for 120 minutes, and A₀ may be a quantum yield of the quantum dot before the emitting of the blue light.

In an embodiment, a ratio of the total number of indium atoms and gallium atoms in the entire quantum dot to the number of copper atoms in the entire quantum dot may be in a range of about 1 to about 10.

In an embodiment, a thickness of the shell may be equal to or less than about 5 nm.

An embodiment provides a light emitting element which may include a first electrode, a hole transport region disposed on the first electrode, an emission layer disposed on the hole transport region and including a quantum dot, an electron transport region disposed on the emission layer, and a second electrode disposed on the electron transport region, wherein
the quantum dot may include: a core including copper, indium, gallium, and sulfur; and a shell surrounding the core and including fluorine and a Group II-VI compound.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of an electronic device according to an embodiment;

FIG. 2 is a schematic exploded perspective view of an electronic device according to an embodiment;

FIG. 3 is a schematic cross-sectional view of a display device according to an embodiment;

FIG. 4 is a schematic cross-sectional view of a light emitting element according to an embodiment;

FIG. 5 is a schematic view of a structure of a quantum dot according to an embodiment;

FIG. 6 is a schematic enlarged plan view of a portion of a display device according to an embodiment;

FIG. 7 is a schematic cross-sectional view of a display device according to an embodiment, which corresponds to line II-II′ of FIG. 6;

FIG. 8 is a schematic cross-sectional view of a display device according to an embodiment;

FIG. 9 is a flowchart of a method for preparing a quantum dot according to an embodiment;

FIG. 10 is a transmission electron microscopy (TEM) image of the CuInGaS cores used in Examples 1 to 5 and Comparative Example 1;

FIG. 11A is a TEM image of quantum dots of Comparative Example 1;

FIGS. 11B and 11C are each an X-ray photoelectron spectroscopy (XPS) spectrum of the quantum dots of Comparative Example 1;

FIG. 12A is a TEM image of quantum dots of Example 3; and

FIGS. 12B and 12C are each an XPS spectrum of quantum dots of Example 3.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “Group” refers to a Group of the IUPAC periodic table.

In the specification, “Group II” may include a Group IIA element and a Group IIB element. For example, a Group II element may be magnesium (Mg) or zinc (Zn), but is not limited thereto.

In the specification, “Group VI” may include a Group VIA element and a Group VIB element. For example, a Group VI element may be oxygen (O), sulfur(S), selenium (Se), or tellurium (Te), but is not limited thereto.

In the specification, an average size of a group of quantum dots may be expressed by quantifying the particle diameter through various measurement methods, which may include a mode diameter representing a maximum value of a distribution, a median diameter corresponding to a median value of an integral distribution curve, various average diameters (e.g., number average, length average, area average, mass average, volume average, etc.), and the like. In the specification, an average particle diameter may be expressed as a number average diameter, which may be obtained by measuring D50 (a particle diameter at a point at which a distribution ratio is 50%), unless otherwise stated.

Hereinafter, a quantum dot according to embodiments, a light emitting element, and a display device including the same will be described with reference to the accompanying drawings.

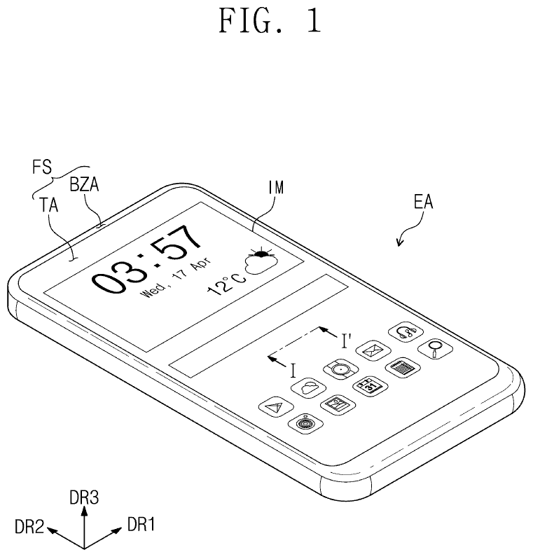

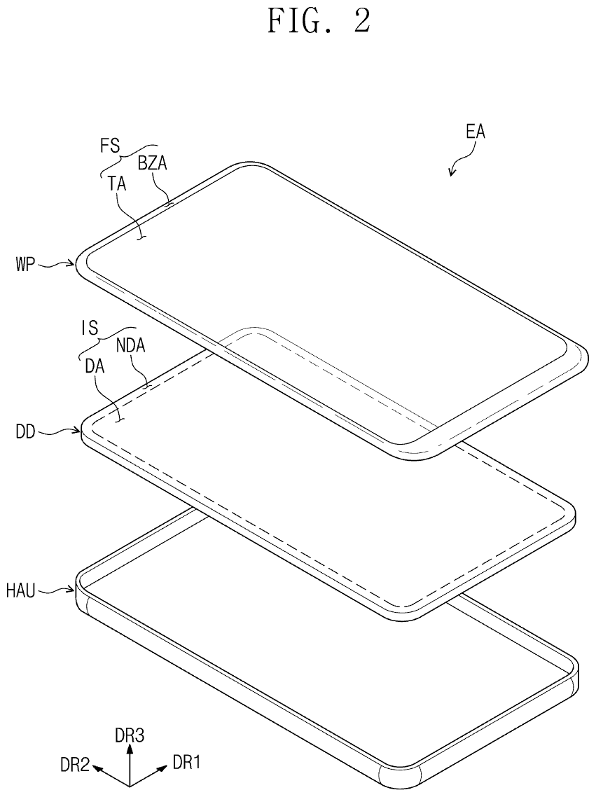

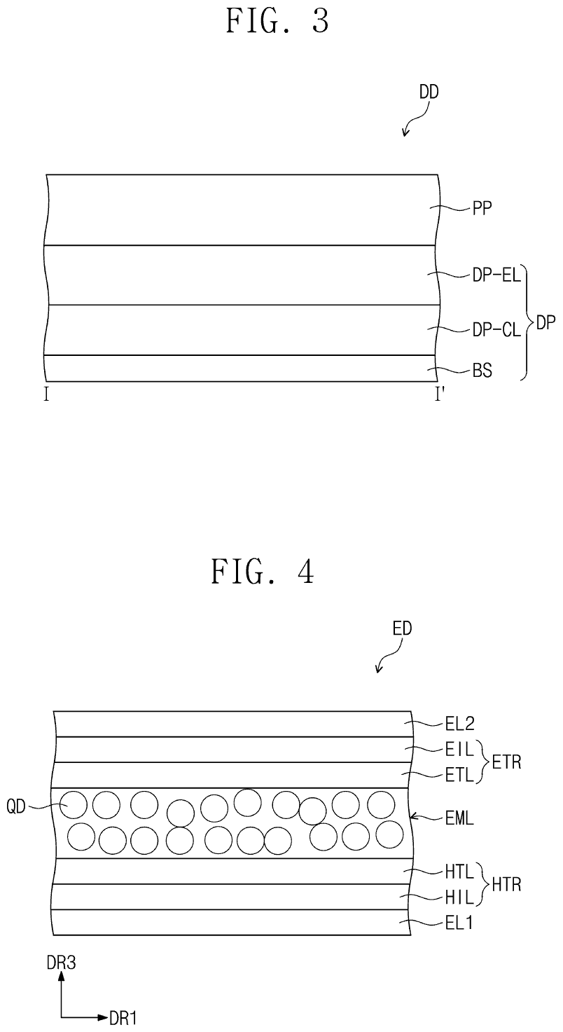

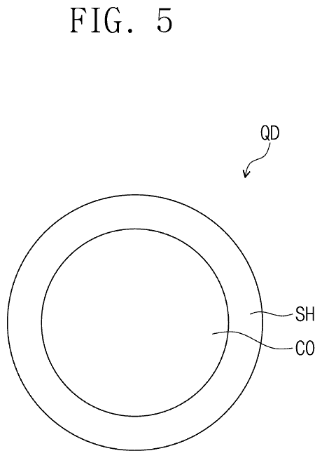

FIG. 1 is a schematic perspective view of an electronic device EA according to an embodiment. FIG. 2 is a schematic exploded perspective view of an electronic device EA according to an embodiment. FIG. 3 is a schematic cross-sectional view of a display device according to an embodiment. FIG. 4 is a schematic cross-sectional view of a light emitting element ED according to an embodiment.

In an embodiment, an electronic device EA may be a large-sized electronic device such as a television set, a monitor, or an outdoor billboard. In another embodiment, the electronic device EA may be a small-sized or a medium-sized electronic device such as a personal computer, a laptop computer, a personal digital terminal, a car navigation unit, a game console, a smartphone, a tablet, and a camera. These are merely presented as an example, and other electronic devices may be employed. As an example, a smartphone may be shown as an embodiment of the electronic device EA.

The electronic device EA may include a display device DD and a housing HAU. The display device DD may display an image IM through a display surface IS, and a user may view an image provided through a transmission region TA corresponding to a front surface FS of the electronic device EA. The image IM may include a still image as well as a dynamic image. FIG. 1 shows that the front surface FS is parallel to a plane defined by a first direction DR1 and a second direction DR2 crossing the first direction DR1. However, this is presented as an example, and in another embodiment, the front surface FS of the electronic device EA may have a curved shape.

Among the normal directions of the front surface FS of the electronic device EA, for example, a thickness direction of the electronic device EA, a direction in which the image IM is displayed is indicated by a third direction DR3. A front surface (or an upper surface) and a rear surface (or a lower surface) of each member may be separated by the third direction DR3.

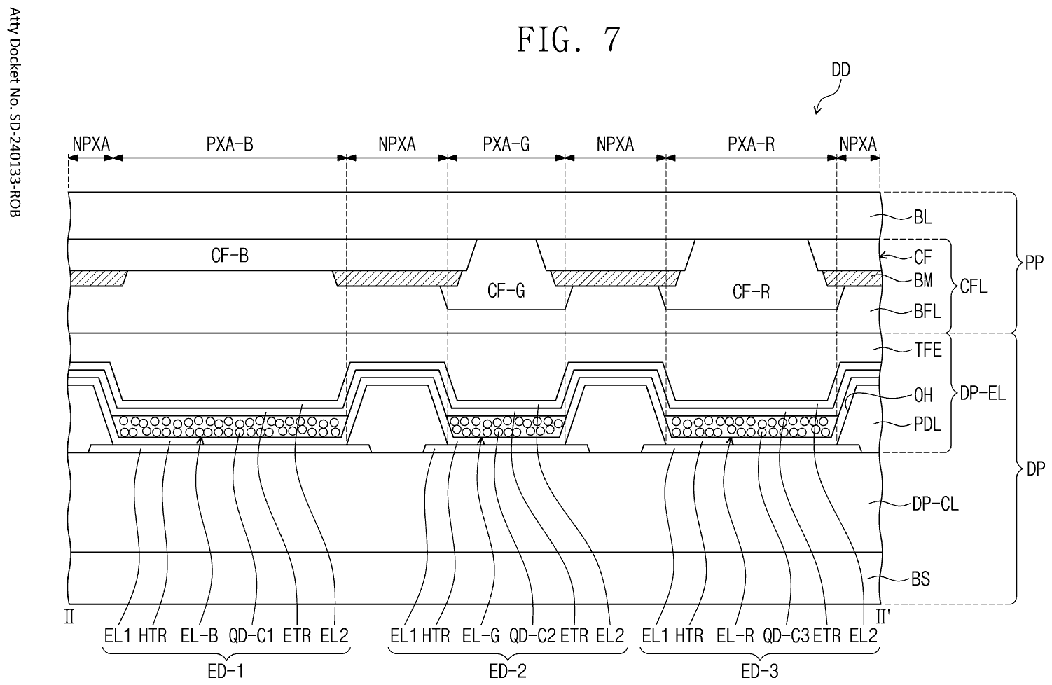

A fourth direction DR4 (see FIG. 6) may be a direction between the first direction DR1 and the second direction DR2. The fourth direction DR4 may be positioned on a plane parallel to the plane defined by the first direction DR1 and the second direction DR2. The directions indicated by the first to fourth directions DR1, DR2, DR3 and DR4 are relative concepts, and may thus be changed to other directions.

Although not shown in the drawing, the electronic device EA may include a foldable display device having a folding region and a non-folding region, or a bending display device having at least one bent portion.

The electronic device EA may include a display device DD and a housing HAU. The front surface FS of the electronic device EA may correspond to a front surface of the display device DD, and may correspond to a front surface of a window WP. Accordingly, the like reference characters will be given for the front surface FS of the electronic device EA, the front surface FS of the display device DD, and the front surface FS of the window WP.

The housing HAU may accommodate the display device DD. The housing HAU may be disposed covering the display device DD, such that the top surface, the display surface IS of the display device DD is exposed. The housing HAU may cover the side surface and the bottom surface of the display device DD and may expose the entire top surface thereof. However, the embodiments are not limited thereto, and the housing HAU may cover a portion of the top surface of the display device DD as well as the side surface and the bottom surface thereof.

In the electronic device EA according to an embodiment, the window WP may include an optically transparent insulating material. The window WP may include a transmission region TA and a bezel region BZA. The front surface FS of the window WP including the transmission region TA and the bezel region BZA corresponds to the front surface FS of the electronic device EA.

In FIGS. 1 and 2, the transmission region TA is shown in a rectangular shape with vertices rounded. However, this is only an example, and the transmission region TA may have various shapes and is not limited to any one embodiment.

The transmission region TA may be an optically clear region. The bezel region BZA may have a light transmittance relatively lower than the transmission region TA. The bezel region BZA may have a color (e.g., a desired or a selectable color). The bezel region BZA may be adjacent to the transmission region TA, and may surround the transmission region TA. The bezel region BZA may define the shape of the transmission region TA. However, embodiments are not limited to the one shown, and the bezel region BZA may be disposed adjacent to only one side of the transmission region TA, and a part thereof may be omitted.

The display device DD may be disposed under the window WP. In the specification, “below” may indicate a direction opposite to the direction in which the display device DD provides an image.

In an embodiment, the display device DD may be configured to generate an image IM. The image IM generated in the display device DD may be displayed on the display surface IS, and may be viewed by a user through the transmission region TA from the outside. The display device DD includes a display region DA and a non-display region NDA. The display region DA may be a region activated in response to an electrical signal. The non-display region NDA may be a region covered by the bezel region BZA. The non-display region NDA may be adjacent to the display region DA. The non-display region NDA may surround the display region DA.

Referring to FIG. 3, the display device DD may include a display panel DP and a light control layer PP disposed on the display panel DP. The display panel DP may include a display element layer DP-EL. The display element layer DP-EL may include a light emitting element ED.

The light control layer PP may be disposed on a display panel DP to control light that is reflected at the display panel DP from an external light. For example, the light control layer PP may include a polarizing layer or a color filter layer.

In an embodiment, the display panel DP of the display device may be a light emitting display panel. For example, the display panel DP may be a quantum dot light emitting display panel including a quantum dot light emitting element. However, embodiments are not limited thereto.

The display panel DP may include a base substrate BS, a circuit layer DP-CL disposed on the base substrate BS, and the display element layer DP-EL disposed on the circuit layer DP-CL.

The base substrate BS may provide a base surface on which the display element layer DP-EL is disposed. The base substrate BS may be a glass substrate, a metal substrate, a plastic substrate, or the like. However, embodiments are not limited thereto, and the base substrate BS may include an inorganic layer, an organic layer, or a composite material layer. The base substrate BS may be a flexible substrate which is readily bendable or foldable.

In an embodiment, the circuit layer DP-CL is disposed on the base substrate BL, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting element ED of the element layer DP-EL.

FIG. 4 is a schematic cross-sectional view of a light emitting element ED according to an embodiment. Referring to FIG. 4, the light emitting element ED according to an embodiment includes a first electrode EL1, a second electrode EL2 facing the first electrode EL1, and functional layers disposed between the first electrode EL1 and the second electrode EL2 and having an emission layer EML.

The functional layers may include a hole transport region HTR disposed between the first electrode EL1 and the emission layer EML, and an electron transport region ETR disposed between the emission layer EML and the second electrode EL2. Although not shown in the drawing, a capping layer may be further disposed on the second electrode EL2 in an embodiment.

The hole transport region HTR and the electron transport region ETR may each include sub-functional layers. For example, the hole transport region HTR may include a hole injection layer HIL and a hole transport layer HTL as sub-functional layers, and the electron transport region ETR may include an electron injection layer EIL and an electron transport layer ETL as sub-functional layers. However, the embodiments are not limited thereto, and the hole transport region HTR may further include an electron blocking layer EBL (not shown) as a sub-functional layer, and the electron transport region ETR may further include a hole blocking layer (not shown) as a sub-functional layer.

In the light emitting element ED according to an embodiment, the first electrode EL1 may have conductivity. The first electrode EL1 may be formed of a metal alloy or a conductive compound. The first electrode EL1 may be an anode. The first electrode EL1 may be a pixel electrode.

In the light emitting element ED according to an embodiment, the first electrode EL1 may be a reflective electrode. However, embodiments are not limited thereto. For example, the first electrode EL1 may be a transmissive electrode or a transflective electrode. If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In another embodiment, the first electrode EL1 may have a multilayer structure including a reflective layer or a transflective layer formed of the above-described material, and a transmissive conductive layer formed of indium tin oxide (ITO), indium zinc oxide (IZO), zinc oxide (ZnO), indium tin zinc oxide (ITZO), and the like. For example, the first electrode EL1 may include a multilayered metal layer or a structure in which metal layers of ITO/Ag/ITO are stacked.

The hole transport region HTR may be provided on the first electrode EL1. The hole transport region HTR may include a hole injection layer HIL, a hole transport layer HTL, etc. The hole transport region HTR may further include at least one of a hole buffer layer (not shown) or an electron blocking layer EBL, in addition to the hole injection layer HIL and the hole transport layer HTL. The hole buffer layer (not shown) may compensate for a resonance distance according to the wavelength of light emitted from the emission layer EML, and may thus increase luminous efficiency. Materials which may be included in the hole transport region HTR may be used as materials included in the hole buffer layer (not shown). The electron blocking layer EBL (not shown) may prevent electrons from being injected from the electron transport region ETR to the hole transport region HTR.

The hole transport region HTR may be a single layer consisting of a single material, a layer including different materials, or a structure including multiple layers including different materials. For example, the hole transport region HTR may be a structure including different materials, or may be a structure in which a hole injection layer HIL/hole transport layer HTL, a hole injection layer HIL/hole transport layer HTL/hole buffer layer (not shown), a hole injection layer HIL/hole buffer layer (not shown), a hole transport layer HTL/hole buffer layer (not shown), or a hole injection layer HIL/hole transport layer HTL/electron blocking layer EBL (not shown) are stacked in its respective order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the hole injection layer HIL may include a phthalocyanine compound such as copper phthalocyanine; N,N-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine] (m-MTDATA), 4,4′,4″-tris(N,N-diphenylamino) triphenylamine (TDATA), 4,4′,4″-tris{N,-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N-diphenyl-benzidine (NPD), triphenylamine-containing polyetherketone (TPAPEK), 4-isopropyl-4′-methyldiphenyliodonium tetrakis(pentafluorophenyl) borate, dipyrazino[2,3-f: 2′,3′-h]quinoxaline-2,3,6,7,10,11-hexacarbonitrile (HAT-CN), etc.

In an embodiment, the hole transport layer HTL may include materials of related art. For example, the hole transport layer HTL may further include carbazole derivatives such as N-phenyl carbazole and polyvinyl carbazole, fluorene derivatives, N,N′-bis(3-methylphenyl)-N,N′-diphenyl-[1,1-biphenyl]-4,4′-diamine (TPD), triphenylamine derivatives such as 4,4′,4″-tris(N-carbazolyl)triphenylamine (TCTA), N,N′-di(naphthalene-1-yl)-N,N′-diphenyl-benzidine (NPD), 4,4-cyclohexylidene bis[N,N-bis(4-methylphenyl]benzenamine] (TAPC), 4,4′-bis[N,N′-(3-tolyl)amino]-3,3-dimethylbiphenyl (HMTPD), 1,3-Bis(N-carbazolyl)benzene (mCP), etc.

A thickness of the hole transport region HTR may be in a range of about 5 nm to about 1,500 nm. For example, the thickness of the hole transport region HTR may be in a range of about 10 nm to about 500 nm. For example, a thickness of the hole injection layer HIL may be in a range of about 3 nm to about 100 nm, and a thickness of the hole transport layer HTL may be in a range of about 3 nm to about 100 nm. For example, a thickness of the electron blocking layer EBL (not shown) may be in a range of about 1 nm to about 100 nm. If the thicknesses of the hole transport region HTR, the hole injection layer HIL, the hole transport layer HTL, and the electron blocking layer EBL (not shown) satisfy the above-described ranges, satisfactory hole transport properties may be achieved without a substantial increase in driving voltage.

The emission layer EML may be provided on the hole transport region HTR. The emission layer EML may include quantum dots QD.

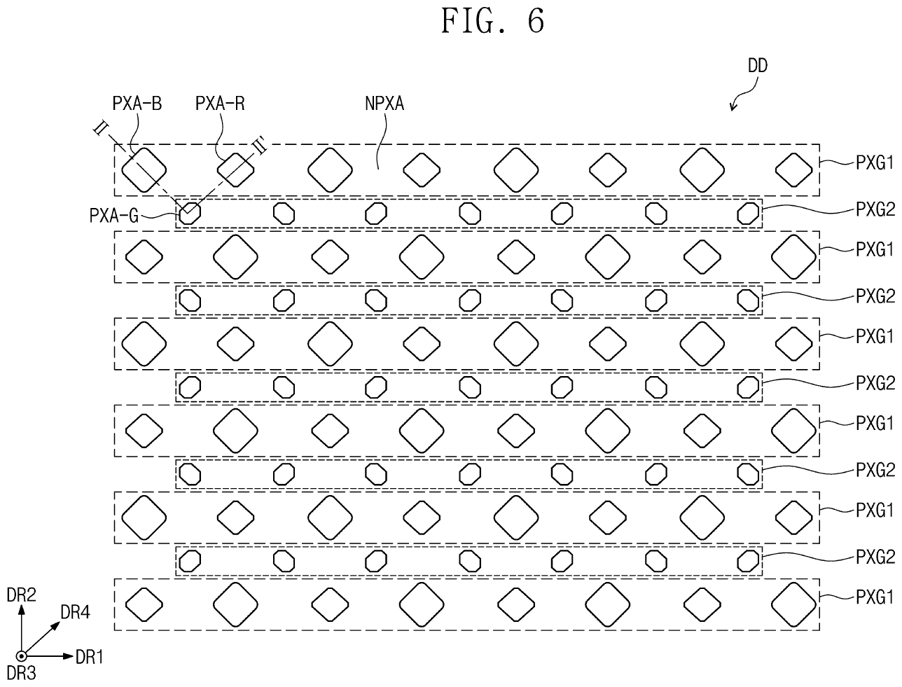

The quantum dots QD in the emission layer EML may form a layer. For example, in FIG. 4, the quantum dots QD having a circular cross-section may be arranged to form two layers, but embodiments are not limited thereto. For example, the arrangement of the quantum dots QD may vary with the thickness of the emission layer EML, the shape of the quantum dots QD in the emission layer EML, and the average particle diameter of the quantum dots QD. For example, in the emission layer EML, the quantum dots QD may be aligned to be adjacent to each other to form a single layer, or may be aligned to form multiple layers such as two or three layers. The quantum dot QD according to an embodiment will be described in detail with reference to FIGS. 5 to 7.

In the light emitting element ED according to an embodiment, an emission layer EML may include a host and a dopant. In an embodiment, the emission layer EML may include a quantum dot QD as a dopant material. In an embodiment, the emission layer EML may further include a host material.

In the light emitting element ED according to an embodiment, the emission layer EML may emit fluorescence. For example, the quantum dot QD may be used as a fluorescent dopant material.

In the light emitting element ED according to an embodiment, an electron transport region ETR may be provided on the emission layer EML. The electron transport region ETR may include at least one of a hole blocking layer (not shown), an electron transport layer ETL, and an electron injection layer EIL, but the embodiments are not limited thereto.

The electron transport region ETR may be a single layer consisting of a single material, a layer including different materials, or a structure including multiple layers including different materials.

For example, the electron transport region ETR may be a single layer structure consisting of the electron injection layer EIL or the electron transport layer ETL, or may have a structure including an electron injection material and an electron transport material. The electron transport region ETR may be a single layer structure including multiple different materials, or may have a structure in which an electron transport layer ETL/electron injection layer EIL, or a hole blocking layer (not shown)/electron transport layer ETL/electron injection layer EIL are stacked in its respective stated order from the emission layer EML, but embodiments are not limited thereto. For example, the thickness of the electron transport region ETR may be in a range from about 20 nm to about 150 nm.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

When the electron transport region ETR includes the electron transport layer ETL, the electron transport region ETR may include an anthracene-based compound. However, embodiments are not limited thereto. For example, the electron transport region may include tris(8-hydroxyquinolinato)aluminum (Alq₃), 1,3,5-tri[(3-pyridyl)-phen-3-yl]benzene, 2,4,6-tris(3-(pyridin-3-yl) biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri (1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl) anthracene (ADN), or a mixture thereof.

A thickness of the electron transport layer ETL may be in a range of about 10 nm to about 100 nm. For example, the thickness of the electron transport layer ETL may be in a range of about 15 nm to about 50 nm. If the thickness of the electron transport layer ETL satisfies the above-described range, satisfactory electron transport properties may be obtained without substantial increase of a driving voltage.

If the electron transport region ETR includes an electron injection layer EIL, the electron transport region ETR may include: a metal halide such as LiF, NaCl, CsF, RbCl, and RbI; a lanthanide metal such as Yb; a metal oxide such as Li₂O and BaO; or lithium quinolate (LiQ), etc., but embodiments are not limited thereto. The electron injection layer EIL may also be formed of a mixture of an electron transport material and an insulating organometallic salt. For example, the organometallic salt may include metal acetate, metal benzoate, metal acetoacetate, metal acetylacetonate, or metal stearate.

A thickness of the electron injection layer EIL may be in a range of about 0.1 nm to about 10 nm. For example, the thickness of the electron injection layer EIL may be in a range of about 0.3 nm to about 9 nm. If the thickness of the electron injection layer EIL satisfies the ranges described above, satisfactory electron injection properties may be obtained without inducing a substantial increase of a driving voltage.

The electron transport region ETR may include a hole blocking layer (not shown) as described above. For example, the hole blocking layer (not shown) may include at least one of 2,9-dimethyl-4,7-diphenyl-1,10-phenanthroline (BCP) or 4,7-diphenyl-1,10-phenanthroline (Bphen), but embodiments are not limited thereto.

The second electrode EL2 may be provided on the electron transport region ETR. The second electrode EL2 may be a common electrode or a negative electrode. The second electrode EL2 may be a transmissive electrode, a transflective electrode or a reflective electrode. If the second electrode EL2 is the transmissive electrode, the second electrode EL2 may include a transparent metal oxide such as indium tin oxide (ITO), indium zinc oxide (IZO) zinc oxide (ZnO), indium tin zinc oxide (ITZO), etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, a compound thereof (for example, AgYb, a compound of AgMg and MgAg depending on the content thereof), or a mixture thereof (for example, a mixture of Ag and Mg). In another embodiment, the second electrode EL2 may have a multilayer structure including a reflective layer or a transflective layer formed of the above-described materials and a transparent conductive layer formed of indium tin oxide (ITO), indium zinc oxide (IZO) zinc oxide (ZnO), indium tin zinc oxide (ITZO), etc.

Although not shown in the drawings, the second electrode EL2 may be electrically connected to an auxiliary electrode. If the second electrode EL2 is electrically connected to the auxiliary electrode, the resistance of the second electrode EL2 may decrease.

FIG. 5 is a schematic cross-sectional view of a structure of a quantum dot according to an embodiment.

Referring to FIG. 5, the quantum dot QD may include a core CO, and a shell SH surrounding the core CO.

The core CO may include a Group I-III-VI semiconductor compound. The core CO may be a Group I-III-VI quaternary CuInGaS compound. The core CO may include copper (Cu), indium (In), gallium (Ga), and sulfur(S). The core CO may be composed of copper, indium, gallium, and sulfur. For example, the core CO may include a copper atom, an indium atom, a gallium atom, and a sulfur atom. The quantum dot QD according to an embodiment may include the core CO including the Group I-III-VI semiconductor compound, and thus may have a high blue light absorption rate.

In an embodiment, the quantum dot QD may be a non-Cd-based quantum dot. For example, the quantum dot QD may not include cadmium (Cd).

The ratio of the number of atoms of the Group III element to the number of atoms of the Group I element in the quantum dot QD may be in a range of about 1 to about 10. In an embodiment, a ratio of the total number of indium atoms and gallium atoms in the entire quantum dot QD to the number of copper atoms in the entire quantum dot QD may be in a range of about 1 to about 10. For example, when the core CO includes CuInGaS and the shell SH includes ZnS, the ratio of the total number of indium atoms and gallium atoms to the number of copper atoms in the core CO may be in a range of about 1 to about 10. The content of the elements in the quantum dot QD may be measured by X-ray photoelectron spectroscopy (XPS), inductively coupled plasma atomic emission spectroscopy (ICP-AES), or the like, but embodiments are not limited thereto.

In an embodiment, a ratio of the number of atoms of the Group III elements in the quantum dot QD to the number of atoms of the Group I elements in the quantum dot QD may be represented by Expression 1:

$${N}^{I I I} / {N}^{I} \qquad [ Expression l ]$$

In Expression 1, N^{I} is the number of the Group I elements in the quantum dot QD, and N^{III} is the number of the Group III elements in the quantum dot QD.

In an embodiment, the quantum dot QD may have high quantum efficiency and optical stability by adjusting the content of the Group I elements and the content of the Group III elements in the core CO to the above-described range. The quantum dot QD may emit light having a desired maximum emission wavelength by including the content of the Group I elements and the content of the Group III elements in the core CO within the above-described range. By changing the content of the Group I elements and the Group III elements in the core CO within the above-described range, it is possible to adjust the quantum dot QD to a desired emission wavelength. For example, when the content of the elements in the core CO satisfies the above-described range, the quantum dot QD may emit light having an emission wavelength in a range of about 500 nm to about 650 nm. Accordingly, the quantum dot QD may emit green light with high color purity.

An absorption wavelength of the core CO including copper, indium, gallium, and sulfur may be in a range of about 350 nm to about 530 nm. Accordingly, the core CO may absorb blue light in the above-described wavelength range to emit green light or red light. The emission wavelength of the light emitted from the quantum dot QD may be adjusted by adjusting the size of the core CO, the thickness of the shell SH, or the like.

The shell SH may surround the core CO. The shell SH may entirely surround the core CO. Thus, the surface of the quantum dot QD may be defined by the external surface of the shell SH. The core CO may be covered by the shell SH, and the core CO may not be exposed in the quantum dot QD. The shell SH may effectively passivate a defect present on the surface of the core CO to increase the luminous efficiency and enhance the stability of the quantum dot QD.

The shell SH may include fluorine and a Group II-VI semiconductor compound. Examples of a Group II-VI semiconductor compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. In an embodiment, a Group II-VI semiconductor compound may further include a Group I metal and/or a Group IV element. Examples of a Group I-II-VI compound may include a Group II-IV-VI compound such as CuSnS or CuZnS, and ZnSnS, etc.

In an embodiment, the shell SH may include ZnS. The shell SH may be made of ZnS. In an embodiment, the shell SH may include ZnS having a band gap greater than a band gap of the core CO, thereby having improved efficiency and stability.

In an embodiment, the shell SH may include fluorine. For example, fluorine may be derived from hydrofluoric acid used in forming a shell S200 in the method for preparing a quantum dot according to an embodiment which will be described later. For example, some of the hydrofluoric acid reacted with the surface of the core CO in the forming a shell S200 may remain to form the fluorine. The fluorine in the shell SH may be confirmed by X-ray photoelectron spectroscopy (XPS), but embodiments are not limited thereto.

A shell SH may have a single layer structure or a multilayer structure. For example, a shell SH may have a single layer consisting of a single material, a single layer consisting of different materials, or a structure including multiple layers consisting of different materials. When the shell SH has a multilayer structure, the composition of each layer may be different. The composition of the layers may vary discontinuously within the shell SH, or may vary continuously within the shell SH.

In the quantum dot QD, a thickness of the shell SH may be equal to or less than about 5 nm. For example, the thickness of the shell SH may be in a range of about 0.5 nm to about 5 nm. However, the thickness of the shell SH is only an example, and embodiments are not limited thereto.

Since the quantum dot QD according to an embodiment includes the shell SH covering the core CO, passivation effects for the core CO may be excellent. Accordingly, the quantum dot QD according to an embodiment may exhibit high quantum yield characteristics.

In an embodiment, an average particle diameter of the quantum dot QD may be in a range of about 3 nm to about 20 nm. When the quantum dot QD satisfies the average particle diameter range as described above, the quantum dot QD may not only exhibit behavior characteristic of the quantum dot QD, but also have excellent dispersibility. Moreover, the emission wavelength of the quantum dot QD and/or semiconductor characteristics of the quantum dot, and the like may be variously modified by variously selecting the average particle diameter of the quantum dot QD in the aforementioned range.

The form of the quantum dot QD is not particularly limited and may be any form used in the related art. For example, the quantum dot may have a spherical shape, a pyramidal shape, a multi-arm shape, a tetrahedron shape, a cylindrical shape, a rod shape, a triangular shape, a disc shape, a tripod shape, a tetrapod shape, or a cubic shape, or the quantum dot may be in the form of nanoparticles, nanotubes, nanowires, nanofibers, nanoplate particles, etc. In an embodiment, the quantum dot QD may have a spherical shape.

For example, a central wavelength of the quantum dot QD may be in a range of about 500 nm to about 680 nm. For example, the quantum dot QD may emit light having a maximum emission wavelength in a range of about 500 nm to about 680 nm. The quantum dot QD may emit green light. A central wavelength of the quantum dot QD may be in a range of about 500 nm to about 570 nm. For example, the quantum dot QD may emit light having a maximum emission wavelength in a range of about 500 nm to about 570 nm. However, embodiments are not limited thereto, and the quantum dot QD may emit red light. For example, a central wavelength of the quantum dot QD may be in a range of about 630 nm to about 680 nm. For example, the quantum dot QD may emit light having a maximum emission wavelength in a range of about 630 nm to about 680 nm.

In an embodiment, a full width at half maximum (FWHM) of an emission wavelength spectrum of the quantum dot QD may be less than about 80 nm. In an embodiment, the quantum dot QD may have a FWHM of an emission wavelength spectrum equal to or less than about 60 nm. When the FWHM of the quantum dot QD satisfies the above-described range, the color purity and color reproducibility of the quantum dot QD may be improved. Since the light emitted through the quantum dot QD is emitted in all directions, a wide viewing angle may be improved.

Although not shown in the drawings, the quantum dot QD may further include a ligand chemically bonded to the surface thereof. The ligand may be chemically bonded to the surface of the quantum dot QD to passivate the quantum dot QD. For example, the quantum dot QD may further include a ligand chemically bonded to the shell SH. In an embodiment, the ligand may include an organic ligand or halogenated metal.

In an embodiment, the quantum dot QD may have a quantum efficiency retention rate represented by Equation 1 equal to or greater than about 90%. When the quantum efficiency maintenance rate of the quantum dot QD is equal to or greater than about 90%, the quantum dot QD may exhibit excellent chemical stability, and thus, degeneration due to a purification process or an external environment may be suppressed.

$$Quantum yield retention rate = {A}_{1} / A 0 \qquad [ Equation l ]$$

In Equation 1, A1 is a quantum yield of the quantum dot measured when blue light having a brightness of 200 nit is emitted for 120 minutes, and A₀ is a quantum yield of the quantum dot before emitting of the light.

In an embodiment, a quantum yield of the quantum dot QD may be equal to or greater than about 80%. For example, the quantum dot QD may have a quantum yield equal to or greater than about 85%. In the specification, the term “quantum yield” refers to the amount of emitted light compared to the light irradiated to the quantum dot. For example, quantum yield (QY) may be expressed by Equation 2:

$$Q Y = {N}_{E} / {N}_{R} \qquad [ Equation 2 ]$$

In Equation 2, NE is the number of photons emitted from the quantum dot, and NR is the number of photons supplied to the quantum dot.

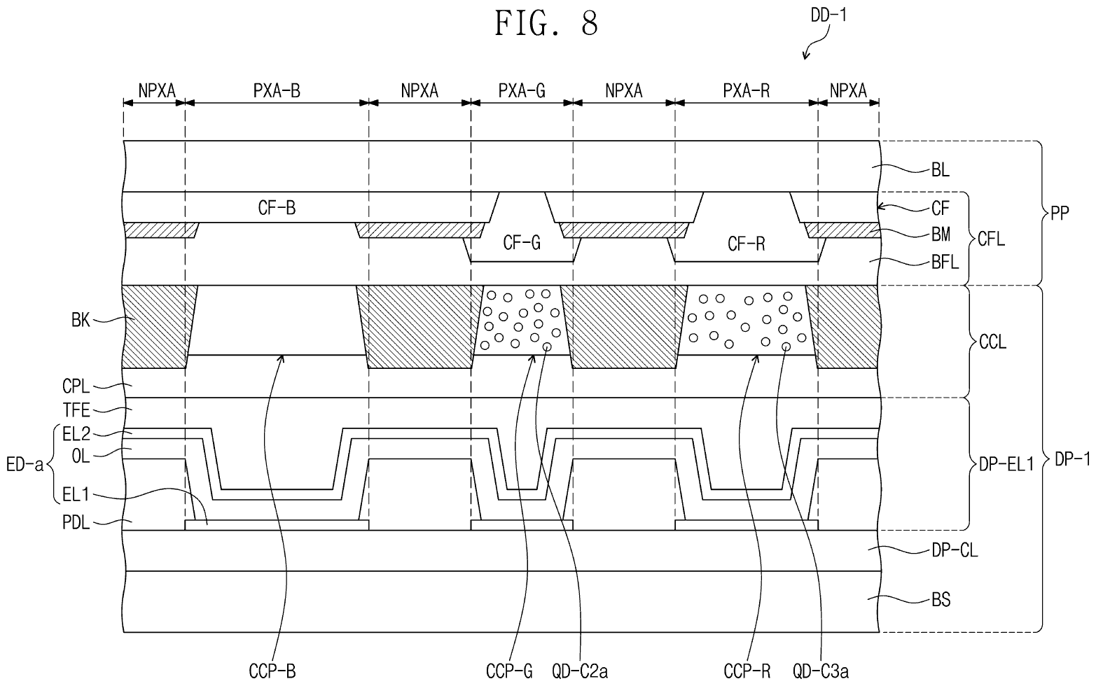

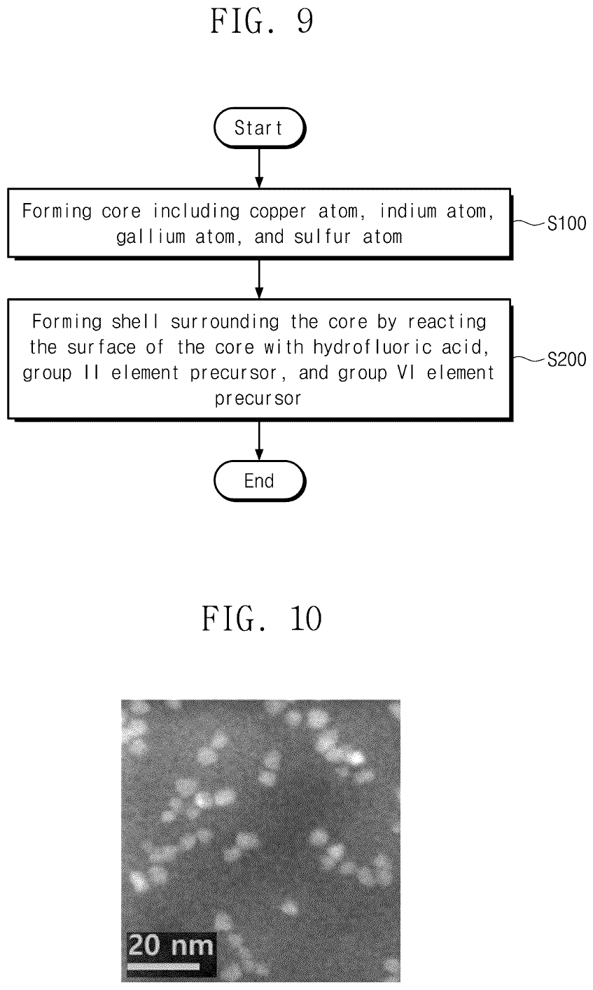

FIG. 6 is a schematic enlarged plan view of a portion of a display device DD according to an embodiment. FIG. 7 is a schematic cross-sectional view of the display device DD according to an embodiment. FIG. 7 shows a part taken along line II-II′ of FIG. 6. FIG. 8 is a schematic cross-sectional view of a display device DD-1 according to another embodiment. FIG. 8 shows a portion of a display region DA in a display panel according to an embodiment. FIG. 8 shows a part taken along line II-II′ of FIG. 6.

Referring to FIGS. 6 to 8, the display device DD may include non-light emitting regions NPXA and light emitting regions PXA-B, PXA-G, and PXA-R. The light emitting regions PXA-B, PXA-G, and PXA-R may be regions which emit light beams generated from the light emitting elements ED-1, ED-2, and ED-3, respectively. The light emitting regions PXA-B, PXA-G, and PXA-R may be spaced apart from each other on a plane.

The light emitting regions PXA-B, PXA-G, and PXA-R may be divided into groups according to the color of light generated from the light emitting elements ED-1, ED-2, and ED-3. In the display devices DD and DD-1 shown in FIGS. 6 to 8, three light emitting regions PXA-B, PXA-G, and PXA-R which respectively emit blue light, green light, and red light respectively are shown by way of example. For example, the display devices DD and DD-1 according to embodiments may each respectively include a blue light emitting region PXA-B, a green light emitting region PXA-G, and a red light emitting region PXA-R, which are separated from one another.

Referring to FIG. 6, the blue light emitting regions PXA-B and the red light emitting regions PXA-R may be alternately arranged in the first direction DR1 to constitute a first group PXG1. The green light emitting regions PXA-G may be arranged in the first direction DR1 to constitute a second group PXG2. The first group PXG1 and the second group PXG2 may be spaced apart in the second direction DR2. Each of the first group PXG1 and the second group PXG2 may be provided in plural. The first groups PXG1 and the second groups PXG2 may be alternately arranged in the second direction DR2. One green light emission area PXA-G may be disposed spaced apart from one blue light emission area PXA-B or one red light emission area PXA-R in the fourth direction DR4. The fourth direction DR4 may be a direction between the first direction DR1 and the second direction DR2. The arrangement structure of the light emitting regions PXA-B, PXA-G, and PXA-R shown in FIG. 6 may be referred to as a pentile configuration (such as PenTile®).

However, embodiments are not limited thereto, and the light emitting regions PXA-R, PXA-B, and PXA-G may have various shapes, such as polygonal shapes or circular shapes, and an arrangement structure of the light emitting regions is not limited thereto. For example, in an embodiment, the light emitting regions PXA-B, PXA-G, and PXA-R may have a stripe configuration in which the blue light emitting region PXA-B, the green light emitting region PXA-G, and the red light emitting region PXA-R are sequentially and alternately arranged in the first direction DR1, or may have a diamond configuration (such as Diamond Pixel®).

Referring to FIG. 7, the light emitting elements ED-1, ED-2, and ED-3 may emit light beams having wavelengths different from each other. For example, in an embodiment, the display device DD may include a first light emitting element ED-1 which emits blue light, a second light emitting element ED-2 which emits green light, and a third light emitting element ED-3 which emits red light. However, embodiments are not limited thereto, and the first to the third light emitting elements ED-1, ED-2, and ED-3 may emit light in a same wavelength range or may emit light in a wavelength different from those of the others.

For example, the blue light emitting region PXA-B, the green light emitting region PXA-G, and the red light emitting region PXA-R of the display device DD may respectively correspond to the first light emitting element ED-1, the second light emitting element ED-2, and the third light emitting element ED-3.

The display device DD according to an embodiment may include light emitting elements ED-1, ED-2, and ED-3, and at least one of the light emitting elements ED-1, ED-2, and ED-3 may include emission layers EML-B, EML-G, and EML-R including quantum dots QD-C1, QD-C2, and QD-C3.

The display device DD according to an embodiment may include a display panel DP including the light emitting elements ED-1, ED-2, and ED-3, and a light control layer PP disposed on the display panel DP. Although not shown in the drawing, the light control layer PP may be omitted from the display device DD according to an embodiment.

The display panel DP may include a base substrate BS, a circuit layer DP-CL, and a display element layer DP-EL provided on the base substrate BS, and the display element layer DP-EL may include a pixel defining film PDL, light emitting elements ED-1, ED-2, and ED-3 disposed between the pixel defining film PDL, and an encapsulation layer TFE disposed on the light emitting elements ED-1, ED-2, and ED-3.

A first emission layer EML-B of a first light-emitting device ED-1 may include a first quantum dot QD-C1. The first quantum dot QD-C1 may emit blue light that is first light.

A second emission layer EML-G of a second light-emitting device ED-2 and a third emission layer EML-R of a third light-emitting device ED-3 may respectively include a second quantum dot QD-C2 and a third quantum dot QD-C3. The second quantum dot QD-C2 and the third quantum dot QD-C3 may respectively emit green light that is second light, and red light that is third light.

At least one of the first to third quantum dots QD-C1, QD-C2, and QD-C3 may be the quantum dot according to the embodiment as described herein. In an embodiment, the second quantum dot QD-C2 may be the quantum dot as described herein. However, embodiments are not limited thereto, and the first to third quantum dots QD-C1, QD-C2, and QD-C3 may each be the quantum dot according to the embodiment as described herein.

In an embodiment, the first to third quantum dots QD-C1, QD-C2, and QD-C3 in the light emitting elements ED-1, ED-2, and ED-3 may be formed of different core materials. In another example, the first to third quantum dots QD-C1, QD-C2, and QD-C3 may be formed of a same core material, or two quantum dots selected from of the first to third quantum dots QD-C1, QD-C2, and QD-C3 may be formed of a same core material, and the other may be formed of a different core material.

In an embodiment, the first to third quantum dots QD-C1, QD-C2, and QD-C3 may have different diameters. For example, the first quantum dot QD-C1 used in the first light emitting element ED-1 emitting light in a relatively short wavelength range may have a smaller average diameter than the second quantum dot QD-C2 of the second light emitting element ED-2 and the third quantum dot QD-C3 of the third light emitting element ED-3 each emitting light in a longer wavelength region.

The relationship of the average diameters of the first to third quantum dots QD-C1, QD-C2, and QD-C3 is not limited to the above limitations. For example, FIG. 7 shows that the first to third quantum dots QD-C1, QD-C2, and QD-C3 are similar in size from one another. However, in another embodiment, the first to third quantum dots QD-C1, QD-C2, and QD-C3 in the light emitting elements ED-1, ED-2, and ED-3 may be different in size. The average diameter of two quantum dots selected from the first to third quantum dots QD-C1, QD-C2, and QD-C3 may be similar, and the remainder may be different.

In the display device DD according to an embodiment, as shown in FIGS. 6 and 7, the areas of the light emitting regions PXA-B, PXA-G, and PXA-R each may be different from one another. The area may be an area in a plan view that is defined by the first direction DR1 and the second direction DR2.

The light emission regions PXA-B, PXA-G, and PXA-R may have different areas according to the color emitted from the emission layers EML-B, EML-G, and EML-R of the light emitting elements ED-1, ED-2, and ED-3. For example, with reference to FIGS. 6 and 7, in the display device DD according to an embodiment, the blue light emitting region PXA-B corresponding to the first light emitting element ED-1, which emits blue light, may have the largest area, and the green light emitting region PXA-G corresponding to the second light emitting element ED-2, which emits green light, may have the smallest area. However, embodiments are not limited thereto. Thus, the light emitting regions PXA-B, PXA-G, and PXA-R may emit light having colors different from blue, green, and red colors, the light emitting regions PXA-B, PXA-G, and PXA-R may have a same area, or the light emitting regions PXA-B, PXA-G, and PXA-R may be provided at a different area ratio than that shown in FIG. 6.

The light emitting regions PXA-R, PXA-G, and PXA-B may each be a region divided by the pixel defining film PDL. The non-light emitting regions NPXA may be regions between the adjacent light emitting regions PXA-B, PXA-G, and PXA-R, which correspond to the pixel defining film PDL. In the specification, the light emitting regions PXA-B, PXA-G, and PXA-R may respectively correspond to pixels. The pixel defining film PDL may divide the light emitting elements ED-1, ED-2, and ED-3. The emission layers EML-B, EML-G, and EML-R of the light emitting elements ED-1, ED-2, and ED-3 may be disposed and separated in an opening OH defined by the pixel defining film PDL.

The pixel defining film PDL may be formed of a polymer resin. For example, the pixel defining film PDL may include a polyacrylate-based resin or a polyimide-based resin. The pixel defining film PDL may further include an inorganic material in addition to the polymer resin. The pixel defining film PDL may include a light absorbing material or a black pigment or a black dye. The pixel definition layer PDL, which may include a black pigment or a black dye, may form a black pixel definition layer. In forming the pixel defining film PDL, carbon black, etc. may be used as the black pigment or the black dye, but embodiments are not limited thereto.

The pixel defining film PDL may be formed of inorganic materials. For example, the pixel defining film PDL may include silicon nitride (SiNₓ), silicon oxide (SiOₓ), silicon oxide (SiOₓN_{y}), etc. The pixel defining film PDL may define light emission areas PXA-B, PXA-G, and PXA-R. The pixel defining film PDL may define the light emitting regions PXA-B, PXA-G, and PXA-R. The light emitting regions PXA-B, PXA-G, and PXA-R and the non-light emitting regions NPXA may be divided by the pixel defining films PDL.

The light emitting elements ED-1, ED-2, and ED-3 may each include a first electrode EL1, a hole transport region HTR, emission layers EML-B, EML-G, and EML-R, an electron transport region ETR, and a second electrode EL2. The description in FIG. 4 may be equally applied to the first electrode EL1, the hole transport region HTR, the electron transport region ETR, and the second electrode EL2, except that the first to third quantum dots QD1, QD2, and QD3 in the emission layers EML-B, EML-G, and EML-R are different from one another in the light emitting elements ED-1, ED-2, and ED-3 in the display device DD according to an embodiment. Although not shown in the drawings, each of the light emitting elements ED-1, ED-2, and ED-3 may further include a capping layer between the second electrode EL2 and the encapsulation layer TFE.

The encapsulation layer TFE may cover the light emitting elements ED-1, ED-2, and ED-3. The encapsulation layer TFE may be a single layer or formed by stacking multiple layers. The encapsulation layer TFE may be a thin film encapsulation layer. The encapsulation layer TFE protects the light emitting elements ED-1, ED-2, and ED-3. The encapsulation layer TFE may cover an upper surface of the second electrode EL2 disposed in the opening OH, and may fill the opening OH.

In FIG. 7, the hole transport region HTR and the electron transport region ETR are shown to be provided as a common layer while covering the pixel defining film PDL, but embodiments are not limited thereto. In an embodiment, the hole transport region HTR and the electron transport region ETR may be disposed in the opening OH defined by the pixel defining film PDL.

For example, when the hole transport region HTR and the electron transport region ETR in addition to the emission layers EML-B, EML-G, and EML-R are provided through an inkjet printing method, the hole transport region HTR, the emission layers EML-B, EML-G, and EML-R, the electron transport region ETR, etc. may be provided corresponding to the defined opening OH between the pixel defining film PDL. However, embodiments are not limited thereto, and as shown in FIG. 7, the hole transport region HTR and the electron transport region ETR may cover the pixel defining film PDL without being patterned, and be provided as one common layer regardless of a method for providing each functional layer.

In the display device DD according to an embodiment shown in FIG. 7, although the thicknesses of the emission layers EML-B, EML-G, and EML-R of the first to third light emitting elements ED-1, ED-2, and ED-3 are shown to be similar to one another, embodiments are not limited thereto. For example, in an embodiment, the thicknesses of the emission layers EML-B, EML-G, and EML-R of the first to third light emitting elements ED-1, ED-2, and ED-3 may be different from one another.

Referring to FIG. 7, the display device DD according to an embodiment may further include a light control layer PP. The light control layer PP may block external light incident to the display panel DP from the outside the display device DD. The light control layer PP may block a part of the external light. The light control layer PP may minimize reflection of the external light.

In an embodiment in FIG. 7, the light control layer PP may include a color filter layer CFL. For example, the display device DD may further include the color filter layer CFL disposed on the light emitting elements ED-1, ED-2, and ED-3 of the display panel DP.

In the display device DD according to an embodiment, the light control layer PP may include a base layer BL and a color filter layer CFL.

The base layer BL may provide a base surface on which the color filter layer CFL is disposed. The base layer BL may be a glass substrate, a metal substrate, a plastic substrate, etc. However, embodiments are not limited thereto, and the base layer BL may include an inorganic layer, an organic layer, or a composite material layer.

The color filter layer CFL may include a light blocking unit BM and a color filter CF. The color filter may include filters CF-B, CF-G, and CF-R. For example, the color filter layer CFL may include a first filter CF-B transmitting a first color light, a second filter CF-G transmitting a second color light, and a third filter CF-R transmitting a third color light. For example, the first filter CF-B may be a blue filter, the second filter CF-G may be a green filter, and the third filter CF-R may be a red filter.

The filters CF-B, CF-G, and CF-R each may include a polymeric photosensitive resin and a pigment or dye. The first filter CF-B may include a blue pigment or dye, the second filter CF-G may include a green pigment or dye, and the third filter CF-R may include a red pigment or dye.

Embodiments are not limited thereto, and the first filter CF-B may not include a pigment or a dye. The first filter CF-B may include a polymer photosensitive resin, but may not include a pigment or a dye. The first filter CF-B may be transparent. The first filter CF-B may be formed of a transparent photosensitive resin.

The light shielding unit BM may be a black matrix. The light shielding unit BM may include an organic light shielding material or an inorganic light shielding material, each including a black pigment or dye. The light blocking unit BM may prevent light leakage, and may separate boundaries between the adjacent filters CF-B, CF-G, and CF-R.

The color filter layer CFL may further include a buffer layer BFL. For example, the buffer layer BFL may be a protective layer which protects the filters CF-B, CF-G, and CF-R. The buffer layer BFL may be an inorganic material layer including at least one inorganic material selected from silicon nitride, silicon oxide, and silicon oxynitride. The buffer layer BFL may be formed of a single layer or multiple layers.

In an embodiment shown in FIG. 7, the first filter CF-B of the color filter layer CFL is shown to overlap the second filter CF-G and the third filter CF-R, but embodiments are not limited thereto. For example, the first to third filters CF-B, CF-G, and CF-R may be divided by the light shielding part BM and not overlap one another. In an embodiment, the first to third filters CF-B, CF-G, and CF-R may be disposed corresponding to the blue light emitting region PXA-B, the green light emitting region PXA-G, and the red light emitting region PXA-R, respectively.

Unlike shown in FIG. 7 and the like, the display device DD according to an embodiment may include a polarizing layer (not shown) as a light control layer PP instead of the color filter layer CFL. The polarizing layer (not shown) may block external light provided to the display panel DP from the outside. The polarizing layer (not shown) may block a part of external light.

In addition, the polarizing layer (not shown) may reduce reflected light generated in the display panel DP by external light. For example, the polarizing layer (not shown) may function to block reflected light of a case where light provided from the outside the display device DD is incident to the display panel DP and exits again. The polarizing layer (not shown) may be a circularly polarizer having a reflection preventing function or the polarizing layer may include a linear polarizer and a λ/4 phase retarder. The polarizing layer (not shown) may be disposed on the base layer BL to be exposed or the polarizing layer (not shown) may be disposed under the base layer BL.

Referring to FIG. 8, the display device DD-1 according to an embodiment may include a light conversion layer CCL disposed on a display panel DP-1. the display device DD-1 may further include a color filter layer CFL. The color filter layer CFL may be disposed between the base layer BL and the light conversion layer CCL.

The display panel DP-1 may be a light emitting display panel. For example, the display panel DP-1 may be an organic electroluminescence display panel or a quantum dot light emitting display panel.

The display panel DP-1 may include a base substrate BS, a circuit layer DP-CL provided on the base substrate BS, and a display element layer DP-EL1.

The display element layer DP-EL1 includes a light emitting element ED-a, and the light emitting element ED-a may include a first electrode EL1 and a second electrode EL2 facing each other, and multiple layers OL disposed between the first electrode EL1 and the second electrode EL2. The layers OL may include a hole transport region HTR (FIG. 4), an emission layer EML (FIG. 4), and an electron transport region ETR (FIG. 4). An encapsulation layer TFE may be disposed on the light emitting element ED-a.

In the light emitting element ED-a, the same content as the one described with reference to FIG. 4 may be applied to the first electrode EL1, the hole transport region HTR, the electron transport region ETR, and the second electrode EL2. However, in the light emitting element ED-a in the display panel DP-1 according to an embodiment, the emission layer may include a host and a dopant which are organic electroluminescent materials or may include the quantum dot according to the embodiment as described above. In the display panel DP-1 according to an embodiment, the light emitting element ED-a may emit blue light.

The light conversion layer CCL may include partition walls BK disposed spaced apart from each other and light control parts CCP-B, CCP-G, and CCP-R disposed between adjacent partition walls BK. The partition walls BK may include a polymer resin and a coloring additive. The partition walls BK may include a light absorbing material, or formed including a pigment or a dye. For example, the partition walls BK may include a black pigment or a black dye to implement a black partition wall. When forming the black partition wall, carbon black or the like may be used as a black pigment or a black dye, but embodiments are not limited thereto.

The light conversion layer CCL may include a first light control part CCP-B which transmits the first light, a second light control part CCP-G including a fourth quantum dot QD-C2a which converts the first light to a second light, and a third light control part CCP-R including a fifth quantum dot QD-C3a which converts the first light to a third light. The second light may be light having a longer wavelength region than the first light, and the third light may be light having a longer wavelength region than the first light and the second light. For example, the first light may be blue light, the second light may be green light, and the third light may be red light. The same content of the quantum dot according to the embodiment as described above may be applied with respect to at least one of the quantum dots QD-C2a and QD-C3a in the light control parts CCP-B, CCP-G, and CCP-R. For example, the same content of the quantum dot according to the embodiment as described above may be applied with respect to the fourth quantum dot QD-C2a which converts the first light to the second light.

The light conversion layer CCL may further include a capping layer CPL. The capping layer CPL may be disposed on the light control parts CCP-B, CCP-G, and CCP-R, and the partition walls BK. The capping layer CPL may serve to prevent penetration of moisture and/or oxygen (hereinafter, referred to as moisture/oxygen). The capping layer may be disposed on the light control parts CCP-B, CCP-G, and CCP-R to prevent the light control parts CCP-B, CCP-G, and CCP-R from being exposed to moisture/oxygen. The capping layer CPL may include at least one inorganic layer.

The display device DD-1 according to an embodiment may include a color filter layer CFL disposed on the light conversion layer CCL, and the descriptions of FIG. 7 may be equally applied to the color filter layer CFL and the base layer BL.

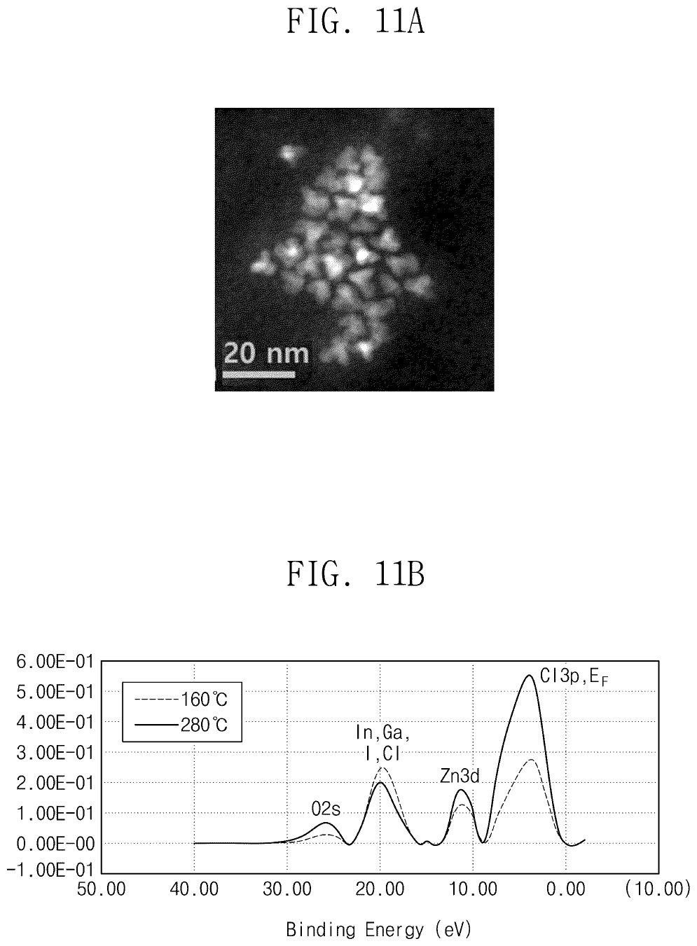

FIG. 9 is a flowchart of a method for preparing a quantum dot according to an embodiment.

Referring to FIG. 9, the method for preparing a quantum dot according to an embodiment includes forming a core S100 and forming a shell surrounding the core S200.

In the method for preparing a quantum dot according to an embodiment, the forming of the core including a copper atom, an indium atom, a gallium atom, and a sulfur atom may be first performed.

In an embodiment, the forming of the core may include providing a first mixture including a ligand and a first precursor material including a copper precursor, an indium precursor, and a gallium precursor, and adding a sulfur precursor to the first mixture to react the first precursor material with the sulfur precursor.

As the starting material for forming the core, the first mixture including the ligand and the first precursor material including the copper precursor, the indium precursor, and the gallium precursor may be used. The providing of the first mixture may include dispersing the first precursor material including the copper precursor, the indium precursor, and the gallium precursor in the ligand. The ligand may be a material that coordinates the surface of the core to be prepared later and improves the dispersibility of the core. The ligand may affect luminescence and electrical characteristics of the prepared quantum dot.

In an embodiment, the ligand may include an organic ligand or halogenated metal.

In an embodiment, the ligand may be any one of a substituted or unsubstituted aliphatic hydrocarbon having 1 to 30 carbon atoms, a substituted or unsubstituted aromatic hydrocarbon having 6 to 30 ring-forming carbon atoms, RCOOH, RNH₂, R₂NH, R₃N, RSH, RH₂PO, R₂HPO, R₃PO, RH₂P, R₂HP, R₃P, ROH, RCOOR′, RPO(OH)₂, or R₂POOH. For example, R and R′ may be each independently a substituted or unsubstituted alkyl group having 1 to 30 carbon atoms or a substituted or unsubstituted alkenyl group having 2 to 30 carbon atoms.

Examples of the ligand may include octadecane, octadecene, methane thiol, ethane thiol, propane thiol, butane thiol, pentane thiol, hexane thiol, octane thiol, dodecane thiol, hexadecane thiol, octadecane thiol, benzyl thiol, methane amine, ethane amine, propane amine, butyl amine, pentyl amine, hexyl amine, octyl amine, dodecyl amine, hexadecyl amine, octadecyl amine, dimethyl amine, diethyl amine, dipropyl amine, oleylamine, trioctylamine, methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenylphosphine, triethylphosphine, ethyldiphenylphosphine, trioctylphosphine, trimethylphosphine oxide, methyldiphenylphosphine oxide, triethylphosphine oxide, ethyldiphenylphosphine oxide, trioctylphosphine oxide, and the like, but embodiments are not limited thereto. The first ligand may be used alone or as a mixture of two or more.

In an embodiment, the ligand may be oleylamine. When the ligand includes oleylamine, reaction stability may be maintained when the sulfur precursor is added to the first mixture in the forming of the core.

Before or after the dispersing of the first precursor material in the ligand, dissolving the first precursor material in a solvent may be performed, but embodiments are not limited thereto. When the first precursor material is preliminarily dissolved in the solvent, the solvent may include at least one of hexane, toluene, chloroform, dimethyl sulfoxide, cyclohexylbenzene, hexadecane, or dimethyl formamide. However, embodiments are not limited thereto.

The first precursor material may include copper precursor, indium precursor, and gallium precursor materials. The copper precursor, indium precursor, and gallium precursor may be each independently a metal powder, a metal halide, a metal sulfate, a metal acetylacetonate, a metal hydroxide, a metal oxide, a metal nitrate, a metal carboxylate, an alkylated metal compound, or a combination thereof.

The copper precursor may be at least one of copper halide, copper acetate, and copper nitrate. For example, the copper precursor may be copper iodide. However, embodiments are not limited thereto.

The gallium precursor may be at least one of gallium nitrate, gallium phosphide, gallium (III) acetylacetonate, gallium (III) bromide, gallium (III) chloride, gallium (III) fluoride, gallium (III) iodide, gallium (III) nitrate hydrate, gallium (III) sulfate and gallium (III) sulfate hydrate. For example, the gallium precursor may be gallium iodide.

The indium precursor may be at least one of indium (III) acetylacetonate, indium (III) bromide, indium (III) chloride, indium (III) fluoride, indium (III) iodide, indium (III) acetate, trimethyl indium, alkyl indium, aryl indium, indium (III) myristate, indium (III) myristate acetate, and indium (III) di-myristate acetate. For example, the indium precursor may be indium iodide.

In an embodiment, at least one of the copper precursor, the indium precursor, or the gallium precursor in the first mixture may each be a metal halide. For example, the copper precursor, the indium precursor, and the gallium precursor, which are the first precursor materials for forming the core CO (see FIG. 5), may each be a metal halide. By using a metal halide as the precursor material for forming the core CO (see FIG. 5), the quantum dot QD (see FIG. 5) having a high blue light absorption rate and excellent luminescence characteristics may be achieved.

In an embodiment, the copper precursor may be represented by Formula 1, the indium precursor may be represented by Formula 2, and the gallium precursor may be represented by Formula 3:

CuXₘ [Formula 1]

InXₘ [Formula 2]

GaXₘ [Formula 3]

In Formula 1 to Formula 3, X may be Cl, Br, or I. For example, X may be I.

In Formula 1 to Formula 3, m may be determined according to the valence of Cu, In, or Ga, and may each independently be an integer from 1 to 3. For example, in Formula 1, m may be 1 or 2, and in Formula 3, m may be 3.

Forming a core by adding a sulfur precursor to the first mixture may be performed. The forming of the core may be reacting the first precursor material with the sulfur precursor by adding the sulfur precursor to the first mixture. The forming of the core may be reacting the sulfur precursor with the copper precursor, the indium precursor, and the gallium precursor in the first mixture. The copper precursor, the indium precursor, and the gallium precursor in the first mixture may react with the sulfur precursor to form the core CO (see FIG. 5).

In an embodiment, the sulfur precursor may include at least one of sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, and bis(trimethylsilyl) sulfide. For example, the sulfur precursor may be sulfur-oleylamine.

After adding the sulfur precursor to the first mixture, heat-treatment may be performed. After adding the sulfur precursor to the first mixture, heat-treatment may be performed greater than or equal to a selected heat treatment temperature. However, embodiments are not limited thereto, and after heating the first mixture greater than or equal to a selected heat treatment temperature, the sulfur precursor may be added while maintaining the temperature. The heat treatment temperature may be equal to or greater than about 230° C. For example, the heat treatment temperature may be in a range of about 230° C. to about 350° C. The heat-treating of the reaction solution in which the sulfur precursor is added to the first mixture may be performed at a temperature equal to or greater than about 230° C.

The method for preparing a quantum dot according to an embodiment may further include purifying the prepared core after the forming of the core. The purifying may be performed using chloroform, ethanol, acetone, or any combination thereof. However, embodiments are not limited thereto, and the purifying of the core in the method for preparing a quantum dot may be omitted depending on process conditions.

After the forming of the core S100, the forming of the shell S200 may be performed. The forming of the shell S200 may be achieved by reacting the surface of the core with hydrofluoric acid, the Group II element precursor, and the Group VI element precursor. In an embodiment, the forming of the shell S200 may include reacting the surface of the core with hydrofluoric acid and reacting the surface of the core with the Group II element precursor and the Group VI element precursor.

Providing a second mixture including the core may be performed in order to form a shell. In an embodiment, the providing of the second mixture may include dispersing the core in the ligand. With regard to the ligand in the second mixture, the above-described contents in the forming of the core S100 may be equally applied.

Adding a solution including hydrofluoric acid to the second mixture to react the surface of the core with hydrofluoric acid may be performed. In the forming of the shell S200, hydrofluoric acid may be provided as a solution dissolved in a solvent. The solvent is not particularly limited as long as it is capable of dissolving hydrofluoric acid. For example, the solvent may be water or alcohol.

The hydrofluoric acid added to the second mixture may modify the surface of the core. In an embodiment, halogen anions bonded to the surface of the core may be removed through the reacting the surface of the core with hydrofluoric acid. For example, hydrofluoric acid may react with the surface of the core to remove ligands including the halogen anions bonded to the surface of the core. The ligands including the halogen anions may be derived from the precursor used in the forming of the core. For example, when a metal halide is used as the core-forming precursor, the ligands including the halogen anions derived from the metal halide may be bonded to the surface of the formed core. Such halogen anion-containing ligands may be bonded to the surface of the core to inhibit shell formation. In an embodiment, the halogen anions bonded to the surface of the core may be removed by modifying the surface of the core with hydrofluoric acid, thereby enabling uniform growth of the shell and thus enhancing the passivation effect of the core by the shell. As a result, the electrical and optical properties and thermal stability of the quantum dot may be improved. In the specification, the halogen anion-containing ligand may be referred to as a halogen ligand.

The amount of hydrofluoric acid may be appropriately selected depending on the size and content of the core. For example, the content of the hydrofluoric acid to be added may be appropriately selected depending on the content of the elements in the core. In an embodiment, the number of moles of the hydrofluoric acid may be in a range of about 0.1 times to about 10 times with respect to the total number of moles of the copper element, the indium element, the gallium element, and the sulfur element in the core. For example, the hydrofluoric acid may be added in the range of about 0.1 times to about 10 times with respect to the total number of moles of the copper element, the indium element, the gallium element, and the sulfur element (e.g., the total number of moles of the Cu, In, Ga, and S elements measured by ICP analysis) in the second mixture. For example, the number of moles of the hydrofluoric acid may be in a range of about 2 times to about 7 times with respect to the total number of moles of copper, indium, gallium, and sulfur elements in the core.

In an embodiment, the time for introducing hydrofluoric acid may be adjusted depending on the content of the core, the type of the shell precursor, process conditions, and the like. For example, the hydrofluoric acid may be introduced into the second mixture with a selectable time difference with each of the Group II element precursor and the Group VI element precursor, or may be introduced simultaneously with at least one of the Group II element precursor or the Group VI element precursor.

The hydrofluoric acid may be added to the second mixture with a selectable time difference with each of the Group II element precursor and the Group VI element precursor. In an embodiment, the reacting of the surface of the core with hydrofluoric acid and the reacting of the surface of the core with the Group II element precursor and the Group VI element precursor may be sequentially performed. For example, the forming of the shell S200 may include adding a solvent including hydrofluoric acid to the second mixture including the core, and adding a Group II element precursor and a Group VI element precursor to the second mixture to which the solvent including hydrofluoric acid is added. After the solution including hydrofluoric acid is added to the second mixture in which the purified cores are dispersed in a solvent, a second precursor material including the Group II element precursor and the Group VI element precursor may be added thereto. A shell surrounding the core may be formed by the reaction of the Group II element precursor and Group VI element precursor which are added. In an embodiment, the reacting of the Group II element precursor and the Group VI element precursor may each be performed at a first temperature. For example, after adding the second precursor material to the second mixture, heat-treatment may be performed at the first temperature. However, embodiments are not limited thereto, and the second precursor material may be added thereto while maintaining the temperature after heating the second mixture at the first temperature. In an embodiment, the first temperature may be about 160° C. For example, the first temperature may be in a range of about 160° C. to about 280° C., but embodiments are not limited thereto.

Before the second precursor material is added to the second mixture, reacting the hydrofluoric acid and the core for a selected time may be performed, but embodiments are not limited thereto. The reaction temperature and the reaction time are not particularly limited, and may be appropriately selected depending on the content of the core or the like.

The hydrofluoric acid may be added to the second mixture simultaneously with at least one of the Group II element precursor and the Group VI element precursor. In an embodiment, the forming of the shell S200 may include adding the Group II element precursor and a solvent including hydrofluoric acid to the second mixture including the cores, and adding the Group VI element precursor to the second mixture. The Group II element precursor and the solvent including hydrofluoric acid may be added to the second mixture in which the purified cores are dispersed in the solvent, and may react with the cores for several minutes. The reaction temperature and the reaction time are not particularly limited and may be appropriately selected. After adding the Group VI element precursor to the second mixture, heat-treatment may be performed at a first temperature. The first temperature may be about 160° C. For example, the first temperature may be in a range of about 160° C. to about 280° C., but embodiments are not limited thereto. In the performing of the heat-treatment at the first temperature condition, the Group II element precursor and the Group VI element precursor may react to form a shell surrounding the core.

However, embodiments are not limited thereto, and the reacting of the surface of the core with hydrofluoric acid may be performed through the same process as the reacting of the surface of the core with the Group II element precursor and the Group VI element precursor. For example, the hydrofluoric acid may be introduced simultaneously with the Group II element precursor and the Group VI element precursor.

The adding of the solvent including hydrofluoric acid may be performed at a lower temperature than the reacting of the Group II element precursor and the Group VI element precursor. In an embodiment, the adding of the solvent including hydrofluoric acid may be performed at a second temperature that is lower than the first temperature.

In an embodiment, the reacting of the surface of the core with hydrofluoric acid, the Group II element precursor, and the Group VI element precursor may be performed under an inert gas atmosphere. The inert gas may include not only a noble gas having low reactivity, but also nitrogen having relatively low reactivity compared to other gases.

The Group II precursor may include a zinc precursor. For example, the zinc precursor may be one or more of dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc peroxide, zinc perchlorate, and zinc sulfate. However, embodiments are not limited thereto.

The Group VI precursor may be one or more of sulfur, trialkylphosphine sulfide, trialkenylphosphine sulfide, alkylamino sulfide, alkenylamino sulfide, alkylthiol, selenium, trialkylphosphine selenide, trialkenylphosphine selenide, alkylamino selenide, alkenylamino selenide, trialkylphosphine telluride, trialkenylphosphine telluride, alkylamino telluride, and alkenylamino telluride. However, embodiments are not limited thereto.

In an embodiment, the Group VI precursor may include a sulfur precursor. The sulfur precursor used in the forming of the shell S200 may be at least one of sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, and bis(trimethylsilyl) sulfide. For example, the sulfur precursor may be sulfur-trioctylphosphine (S-TOP).

In an embodiment, the sulfur precursor used in the forming of the core may be the same as the sulfur precursor used in the forming of the shell. However, embodiments are not limited thereto, and the sulfur precursor used in the forming of the core may be different from the sulfur precursor used in the forming of the shell. In the specification, the sulfur precursor used in the forming of the core may be referred to as a first sulfur precursor, and the sulfur precursor used in the forming of the shell may be referred to as a second sulfur precursor.

The method for preparing a quantum dot according to an embodiment may further include degassing the second mixture at a third temperature before the reacting of the surface of the core with hydrofluoric acid, the Group II element precursor, and the Group VI element precursor. In an embodiment, the third temperature is not particularly limited, but may be at a temperature equal to or greater than about 110° C. For example, the second temperature may be in a range of about 120° C. to about 200° C.

The quantum dot QD (see FIG. 5) including the core CO (see FIG. 5) and the shell SH (see FIG. 5) surrounding the core CO (see FIG. 5) may be formed through the forming of the shell according to an embodiment S200. The method for preparing a quantum dot according to an embodiment may further include purifying the quantum dot formed after the forming of the shell S200. The purifying may be performed using chloroform, ethanol, acetone, or any combination thereof. However, embodiments are not limited thereto, and the purifying of the quantum dot in the method for preparing a quantum dot may be omitted depending on process conditions.

When the shell SH (see FIG. 5) has a multilayer structure, the forming of the shell S200 may be continuously performed two or more times. Any one of the type and content of the precursor, and reaction temperatures may be different, but embodiments are not limited thereto. When the forming of the shell S200 is continuously performed two or more times, the adding of the solution including hydrofluoric acid may be omitted from the second forming of the shell, but embodiments are not limited thereto.

The method for preparing the quantum dot QD according to an embodiment may further include ashing the quantum dot QD (see FIG. 5) prepared after the forming of the shell. The high-purity quantum dot may be prepared through cooling the mixture in which the quantum dots are formed to room temperature, purifying, and redispersing the mixture. The purifying and redispersing may further include adding a nonsolvent to the mixture in which the quantum dots are formed to separate the quantum dots. The nonsolvent may be a polar solvent that is mixed with the organic solvent used in the reaction but cannot disperse the quantum dots.

The nonsolvent may be determined depending on the organic solvent used in the reaction. The nonsolvent may be at least one of acetone, ethanol, butanol, isopropanol, ethanediol, water, tetrahydrofuran, dimethyl sulfoxide, diethyl ether, formaldehyde, acetaldehyde, and ethylene glycol. However, embodiments are not limited thereto.

In an embodiment, separation of quantum dots may be performed by using centrifugation, precipitation, chromatography, or distillation. The separated quantum dots may be added to a cleaning solvent to be cleaned as necessary. The cleaning solvent is not particularly limited, and hexane, heptane, octane, chloroform, toluene, benzene, or the like may be used as the cleaning solvent.

Hereinafter, with reference to Examples and Comparative Examples, the quantum dot according to an embodiment will be described. The embodiments described below are only examples to assist in understanding the disclosure, and the scope thereof is not limited thereto.

### EXAMPLES AND COMPARATIVE EXAMPLES

### Synthesis of Example 1

### Step 1: Synthesis of CuInGaS Core

To a three-neck flask, 0.12 mmol of CuI, 0.6 mmol of InI, and 1.4 mmol of Gal were added and mixed together with 10 mL of oleylamine and 10 mL of 1-octadecene. The resultant mixture was degassed at about 120° C. for about 30 minutes, and stirred to remove oxygen and moisture therein to form a reaction solution. 1.8 mmol of sulfur-oleylamine and 4.6 mmol of 1-dodecanethiol were introduced to the reaction solution in an N2 atmosphere and maintained at a temperature equal to or greater than about 200° C. for a selected time to synthesize a CuInGaS core.

### Step 2: Hydrofluoric Acid Treatment and Growth of ZnS Shell

The synthesized CuInGaS core was diluted in toluene, precipitated with ethanol, purified. After adding the CuInGaS core to 15 mL of tri-n-octylamine, which had been degassed at about 120° C., 1.4 mmol of zinc oleate, 1.4 mmol of a sulfur-tri-n-octylphosphine, and a hydrofluoric acid solution in water were added to resultant mixture and maintained at a temperature equal to or greater than about 200° C. for a selected time to form a ZnS shell. The number of moles of hydrofluoric acid used in Example 1 is 0.4 times with respect to the total number of moles of Cu, In, Ga, and S elements in the CuInGaS core used above.

### Synthesis of Example 2

A quantum dot was prepared in the same manner as in Example 1, except that an amount of hydrofluoric acid injected was 1.9 times greater compared to the amount of hydrofluoric acid injected in Example 1.

### Synthesis of Example 3

A quantum dot was prepared in the same manner as in Example 1, except that an amount of hydrofluoric acid injected was 3.8 times greater compared to the amount of hydrofluoric acid injected in Example 1.

### Synthesis of Example 4

A quantum dot was prepared in the same manner as in Example 1, except that an injection amount of hydrofluoric acid was 7.6 times greater compared to the amount of hydrofluoric acid injected in Example 1.

### Synthesis of Example 5

A quantum dot was prepared in the same manner as in Example 1, except that an injection amount of hydrofluoric acid was 9.5 times greater compared to the amount of hydrofluoric acid injected in Example 1.

### Synthesis of Comparative Example 1

A quantum dot was prepared in the same manner as in Example 1, except that the injection of hydrofluoric acid was omitted in the forming of the ZnS shell compared to Example 1.

The FWHM of the CuInGaS core used in Examples 1 to 5 and Comparative Example 1, and the FWHM, the quantum yield (QY), and the quantum yield retention rate of the quantum dots according to Examples 1 to 5 and Comparative Example 1 were evaluated, and the results are shown in Table 1. To measure the quantum yield, the quantum dots obtained in Examples 1 to 5 and Comparative Example 1 were separated and dispersed in chloroform. The quantum yield of the quantum dot dispersion was measured using QE-2100 equipment from Otsuka Electronics. The quantum yield retention rate was calculated through Equation 1.

TABLE 1

| | | | | | Quantum |
|---|---|---|---|---|---|
| | Amount of | | FWHM of | Quantum | yield |
| | hydrofluoric | FWHM | quantum | yield | retention |
| | acid injected | of core | dot | (%) | rate (%) |
| Comparative | — | 58 nm | 80 nm | 65 | 52 |
| Example 1 | | | | | |
| Example 1 | 0.4 fold | | 66 nm | 79 | 66 |
| Example 2 | 1.9 fold | | 67 nm | 79 | 66 |
| Example 3 | 3.8 fold | | 59 nm | 90 | 98 |
| Example 4 | 7.6 fold | | 76 nm | 85 | 84 |
| Example 5 | 9.5 fold | | 83 nm | 80 | 72 |

Referring to Table 1, it may be confirmed that the quantum dots of Examples show higher quantum yield and higher quantum yield retention rate than those of Comparative Example 1. The quantum dots of Examples exhibit a high quantum yield and a high quantum yield retention rate, so that chemical stability is high, and thus, luminescence characteristics may be improved. Accordingly, the quantum dots of Examples may exhibit higher luminous efficiency than those of Comparative Example 1. It may be confirmed that Example 3 in which the amount of hydrofluoric acid injected is 3.8 times shows high quantum yield equal to or greater than 80%, and high quantum yield retention rate equal to or greater than 90% compared with other Examples. Accordingly, it may be confirmed that when the amount of hydrofluoric acid injected is adjusted to about 2 times to about 7 times with respect to the total number of moles of copper, indium, gallium, and sulfur in the core, characteristics such as quantum yield and stability are further improved.

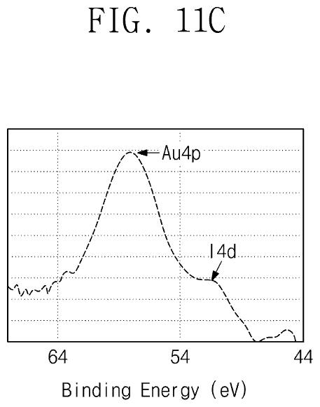

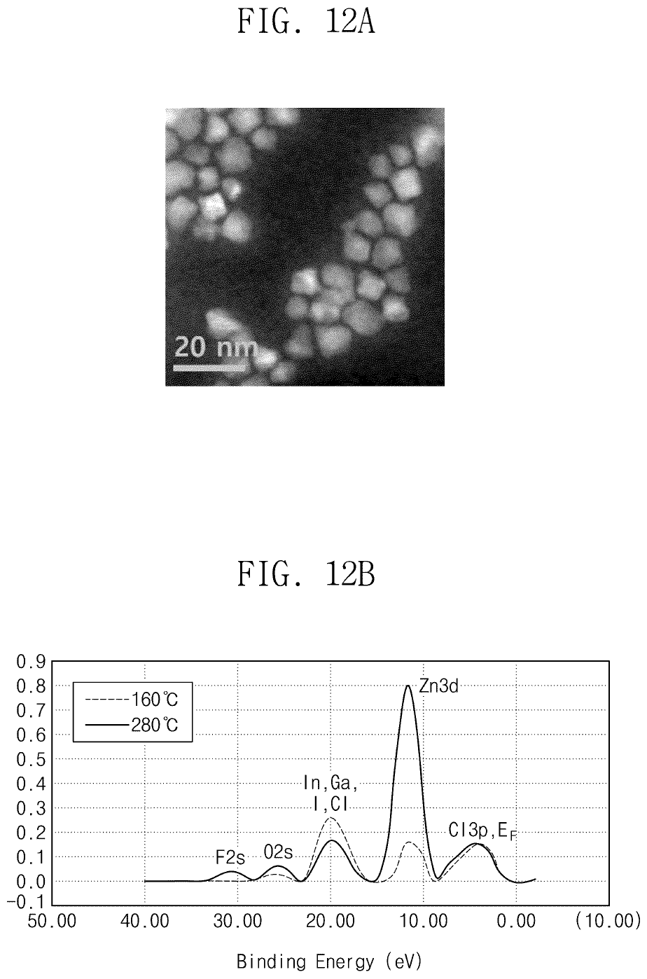

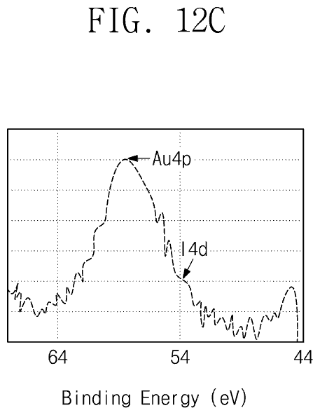

FIG. 10 is a transmission electron microscopy (TEM) image of the CuInGaS cores used in Examples 1 to 5 and Comparative Example 1. FIG. 11A is a TEM image of the quantum dots of Comparative Example 1. FIGS. 11B and 11C are each an XPS spectrum of quantum dots of Comparative Example 1. FIG. 12A is a TEM image of the quantum dots of Example 3. FIGS. 12B and 12C are each a an XPS spectrum of quantum dots of Example 3. X-ray photoelectron spectroscopy (XPS) analysis was performed using Synchrotron XPS in Pohang Accelerator Laboratory (PAL) for Comparative Example 1 and Example 3.

The emission wavelength, the FWHM, the particle diameter, and the shape of the quantum dots according to the CuInGaS core, the quantum dots of Example 3, and the quantum dots of Comparative Example 1 were evaluated, and the results are shown in Table 2.

TABLE 2

| | Emission | | Particle | |
|---|---|---|---|---|
| | wavelength | FWHM | diameter | |
| Division | (nm) | (nm) | (nm) | Shape |
| CuInGaS | 620 | 58 | 4.8 | Tetrahedron |
| Core | | | | to Circle |
| Example 3 | 615 | 59 | 7.1 | Circle |
| Comparative | 622 | 80 | 6.0 | Tetrapod |
| Example 1 | | | | |

Referring to Table 1, FIG. 10, FIG. 11A, and FIG. 12A, it may be confirmed that the quantum dot of Example 3 has a higher sphericity than that of Comparative Example 1. It may be confirmed that the shell of the quantum dot of Example 3 is formed to be thicker than that of the quantum dot of Comparative Example 1 with an increased particle diameter size of about 2.3 nm compared to the particle diameter of the CuInGaS core.

Referring to FIGS. 11B and 12B, a peak corresponding to F2s was detected in the XPS spectrum for quantum dots of Example 3, which suggests that some fluorine remains in the shell after surface treatment with the hydrofluoric acid. When comparing the XPS spectra of Example 3 and Comparative Example 1, it may be confirmed that the intensity of the peak corresponding to Zn3d in the reaction temperature range of about 160° C. to about 280° C. in the XPS spectrum of quantum dots of Example 3 was significantly increased compared to that of Comparative Example 1. This suggests that the shell may be formed thick on the CuInGaS core in the quantum dot of Example 3 by the hydrofluoric acid treatment.

Referring to FIGS. 11C and 12C, the I4d peak is detected in the XPS spectrum of quantum dots of Comparative Example 1, but the I4d peak was not detected in the XPS spectrum of quantum dots of Example 3, which means that the halogen ligand bonded to the CuInGaS surface is removed in the hydrofluoric acid surface treatment step. Referring to FIGS. 11B, 11C, 12B, and 12C together, in Example 3, the Zn3d peak rapidly increased as the I4d peak intensity decreased in the XPS spectrum, which suggests that the removal of the halogen ligand bonded to the CuInGaS surface plays an important role in the growth of the ZnS shell.

When the shell grows on the CuInGaS core, it may be difficult for the shell to grow in a spherical shape when the shell is greater than or equal to a particular thickness due to lattice mismatch, crystallographic surface mismatch, and the like between the core and the shell. A halogen ligand derived from a metal halogen precursor used in the formation of the CuInGaS core may serve as a factor that hinders the spherical growth of the shell. Accordingly, as shown in FIG. 11A, when the shell is formed, a branch may be formed in a direction in which the lattice strain of the interface between the core and the shell decreases, and the surface of the core rather than the branch growth direction may be difficult to be sufficiently passivated by the shell. Accordingly, the quantum dot of Comparative Example 1 may exhibit degradation of luminous efficiency and stability as compared with those of Example 3. In comparison, in Example 3, as the shell is formed on the core which is surface-treated with hydrofluoric acid, a thick shell having a uniform thickness may be formed, thereby exhibiting high luminous efficiency and excellent stability. In the quantum dot of Example 3, the halogen ligand described above may be removed from the surface of the core as the core is surface-treated with hydrofluoric acid when the shell is formed, and thus the shell may uniformly grow on the surface of the core. As a result, the surface of the core is sufficiently passivated by the shell, so that the luminous efficiency and stability of the quantum dot may be improved.

As shown in Table 2, it may be confirmed that the CuInGaS core used in the same manner as in Example and Comparative Example exhibits a narrow FWHM of 58 nm, thereby achieving improved color purity or color reproducibility. However, a Group I-III-VI-based quaternary semiconductor compound, such as the CuInGaS quantum dot, has various defects due to an increase in the degree of freedom due to the inclusion of three cations. Accordingly, a method for passivating defects by introducing the shell covering the core may be used. However, when the shell grows on the CuInGaS core, interfacial defects between the core and the shell may be included due to lattice mismatch, crystallographic surface mismatch, and the like between the core and the shell. Such a phenomenon may cause problems such as an increase in the FWHM of quantum dots and a decrease in luminous efficiency. As shown in Table 2, it was confirmed that the FWHM of Comparative Example 1 was significantly increased compared to that of Example 3 with respect to the CuInGaS core, and this is due to causes such as the interfacial defects described above. On the other hand, it may be confirmed that in the case of Example 3, as the core is treated with hydrofluoric acid, the interfacial defect is suppressed, and the amount of the FWHM increased is reduced compared to Comparative Example.

The method for preparing a quantum dot according to an embodiment includes reacting the surface of the core including Cu, In, Ga, and S with hydrofluoric acid to form a thick shell having a uniform thickness, thereby providing improved passivation, and accordingly, optical characteristics and stability of the quantum dot may be increased. For example, the hydrofluoric acid added during the formation of the shell may remove the halogen ligand present on the surface of the CuInGaS core, and thus, a shell having a uniform thickness may be formed under relatively mild conditions. As a result, the shell may effectively passivate the CuInGaS core and simultaneously reduce defects that cause the thermal quenching phenomenon, thereby improving the luminous efficiency and stability of the quantum dot. Accordingly, when the quantum dot prepared by the method for preparing a quantum dot according to an embodiment is applied to a light emitting element, excellent light efficiency and reliability may be secured.

The quantum dot according to an embodiment includes a core treated with hydrofluoric acid, and thus may exhibit high quantum yield and excellent stability.

The method for preparing a quantum dot according to an embodiment may provide the quantum dot exhibiting high quantum yield and excellent stability.

The light emitting element according to an embodiment includes the quantum dot exhibiting high quantum yield and excellent stability, and thus may exhibit improved luminous efficiency characteristics and color reproducibility.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A method for preparing a quantum dot, the method comprising:
forming a core comprising a copper atom, an indium atom, a gallium atom, and a sulfur atom; and
forming a shell surrounding the core by reacting the surface of the core with hydrofluoric acid, a Group II element precursor, and a Group VI element precursor.

2. The method of claim 1, wherein the forming of the shell comprises:
reacting the surface of the core with the hydrofluoric acid; and
reacting the surface of the core with the Group II element precursor and the Group VI element precursor, wherein
halogen ions bonded to the surface of the core are removed through the reacting of the surface of the core with the hydrofluoric acid.

3. The method of claim 1, wherein the number of moles of the hydrofluoric acid is in a range of about 2 times to about 7 times with respect to the total number of moles of the copper atom, the indium atom, the gallium atom, and the sulfur atom.

4. The method of claim 1, wherein the forming of the core comprises:
providing a first mixture including:
a ligand, and
a first precursor material including a copper precursor, an indium precursor, and a gallium precursor; and
adding a sulfur precursor to the first mixture to react the first precursor material with the sulfur precursor.

5. The method of claim 4, wherein the copper precursor, the indium precursor, and the gallium precursor are each a metal halide.

6. The method of claim 4, wherein
the copper precursor is represented by Formula 1,
the indium precursor is represented by Formula 2, and
the gallium precursor is represented by Formula 3:
CuXₘ [Formula 1]
InXₘ [Formula 2]
GaXₘ [Formula 3]
wherein in Formula 1 to Formula 3,
X is Cl, Br, or I, and
m is determined according to the valence of Cu, In, or Ga, and is each independently an integer from 1 to 3.

7. The method of claim 4, wherein the sulfur precursor comprises at least one of sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, and bis(trimethylsilyl) sulfide.

8. The method of claim 1, wherein the forming of the shell comprises:
adding a Group II element precursor and a solvent comprising the hydrofluoric acid to a second mixture comprising the core; and
adding a Group VI element precursor to the second mixture to react the Group II element precursor and the Group VI element precursor.

9. The method of claim 8, wherein
the reacting of the Group II element precursor and the Group VI element precursor is each performed at a first temperature, and
the first temperature is equal to or greater than about 160° C.

10. The method of claim 9, wherein the adding of the solvent comprising the hydrofluoric acid is performed at a second temperature that is lower than the first temperature.

11. A quantum dot comprising:
a core comprising copper, indium, gallium, and sulfur; and
a shell surrounding the core and comprising fluorine and a Group II-VI compound.

12. The quantum dot of claim 11, wherein the Group II-VI compound is ZnS.

13. The quantum dot of claim 11, wherein an average particle diameter of the quantum dot is in a range of about 3 nm to about 20 nm.

14. The quantum dot of claim 11, wherein a central wavelength of the quantum dot is in a range of about 500 nm to about 650 nm.

15. The quantum dot of claim 11, wherein a full width at half maximum of an emission wavelength spectrum of the quantum dot is equal to or less than about 60 nm.

16. The quantum dot of claim 11, wherein a quantum yield of the quantum dot is equal to or greater than about 80%.

17. The quantum dot of claim 11, wherein
a quantum yield retention rate of the quantum dot is represented by Equation 1, and the quantum yield retention rate is equal to or greater than about 90%:
Quantum yield retention rate=A₁/A₀ [Equation 1]
wherein in Equation 1,
A₁ is a quantum yield of the quantum dot measured when blue light having a brightness of 200 nit is emitted for 120 minutes, and
A₀ is a quantum yield of the quantum dot before the emitting of the blue light.

18. The quantum dot of claim 11, wherein a ratio of the total number of indium atoms and gallium atoms in the entire quantum dot to the number of copper atoms in the entire quantum dot is in a range of about 1 to about 10.

19. The quantum dot of claim 11, wherein a thickness of the shell is equal to less than about 5 nm.

20. A light emitting element comprising:
a first electrode;
a hole transport region disposed on the first electrode;
an emission layer disposed on the hole transport region and comprising a quantum dot;
an electron transport region disposed on the emission layer; and
a second electrode disposed on the electron transport region, wherein
the quantum dot comprises:
a core comprising copper, indium, gallium, and sulfur; and
a shell surrounding the core and comprising fluorine and a Group II-VI compound.
